(19) United States
(12) Patent Application Publication
(10) Pub. No.: US 2017/0212397 A1
(43) Pub. Date: Jul. 27, 2017

(54) ARRAY SUBSTRATE AND LIQUID CRYSTAL DISPLAY

(71) Applicant: Wuhan China Star Optoelectronics Technology Co., Ltd., Wuhan (CN)

(72) Inventor: Shangcao CAO, Shenzhen (CN)

(73) Assignee: Wuhan China Star Optoelectronics Technology Co., L td., Wuhan (CN)

(21) Appl. No.: 15/075,188

(22) Filed: Mar. 20, 2016

(30) Foreign Application Priority Data
Jan. 25, 2016 (CN) 201610049385X

(51) Int. Cl. G02F 1/1362; G02F 1/1335; G02F 1/1368; G02F 1/1333; H01L 27/12; H01L 29/786

(52) U.S. Cl. CPC G02F 1/136213; H01L 27/1222; H01L 27/124; H01L 27/1255; H01L 27/1248; H01L 29/78633; G02F 1/1368; G02F 1/13338; G02F 1/133345; G02F 1/136227; G02F 1/133514

(57) ABSTRACT

The present disclosure discloses an array substrate and a liquid crystal display, the array substrate includes: a substrate; a thin film transistor disposed on the substrate; a conductive layer disposed on the thin film transistor and connected with a drain electrode of the thin film transistor; a common electrode disposed on the conductive layer and forming a first capacitor with the conductor layer; a pixel electrode disposed on the common electrode and connected with the conductive layer, the pixel electrode and the common electrode form a second capacitor. By the method above, the disclosure is capable of increasing capacitance of storage capacitors and improving optical performance of a display.

### FIELD OF THE DISCLOSURE

The present disclosure relates to a display technology field, and more particularly to an array substrate and a liquid crystal display.

### BACKGROUND OF THE DISCLOSURE

A liquid crystal display (LCD) has a broad market prospect due to its good color display, wide angle of view and high contrast.

Time for opening each line of thin film transistors is short, which is hard to achieve the response time of liquid crystals, causing flash of a liquid crystal display. Therefore, a liquid crystal display can include a storage capacitor Cst to avoid the problem, a storage capacitor can be formed by a pixel electrode and a common electrode in some liquid crystal displays. Hence the storage capacitor can be applied to maintain the voltage of the pixel electrode after turning off the thin film transistor for a while, and supply longer response time for liquid crystals.

However, the size of a display needs to be reduced to meet the requirement of thinner, lighter of a liquid crystal display and lower energy consumption, which can cause decrease of a storage capacitor and increase of response time of liquid crystals, flashing in display as a result. Moreover, a display panel produced by fringe field switching (FFS) has a wider angle of view and is insensitive to slight width adjustment of a liquid crystal cell, also known as a hard panel. But a larger storage capacitor is necessary due to TFT in the liquid crystal panel is easily leaking electricity, which can prevent variation of a pixel gray scale in a frame time, the variation of a gray scale can reduce optical property of a liquid crystal panel, such as a cross display and flashing.

### SUMMARY OF THE DISCLOSURE

The technical issue that the disclosure solves is to provide an array substrate and a liquid crystal display, which can increase the capacitance of a capacitor and improve optical property of a display.

A proposal offered by the present disclosure to solve the technical problem above is: providing an array substrate, the array substrate includes: a substrate; a thin film transistor disposed on the substrate; a conductive layer disposed on the thin film transistor and connected with a drain electrode of the thin film transistor; a common electrode disposed on the conductive layer and forming a first capacitor with the conductor layer; a pixel electrode disposed on the common electrode and connected with the conductive layer, the pixel electrode and the common electrode form a second capacitor.

An electrical conductivity of the conductive layer is higher than that of the pixel electrode.

It further includes a touch signal line, the touch signal line and the conductive layer are disposed on the same layer within a same process.

It further includes: a flat layer covering the thin film transistor; a first insulating layer disposed between the flat layer and the conductive layer; a second insulating layer disposed between the conductive layer and the common electrode; a third insulating layer disposed between the common electrode and the pixel electrode.

The conductive layer and the drain electrode of the thin film transistor are connected by through-holes of the first insulating layer and the flat layer.

The pixel electrode and the conductive layer are connected by through-holes of the second insulating layer and the third insulating layer.

The thin film transistor includes: a light shelter layer disposed on the substrate; a buffer layer covering the light shelter layer and the substrate; a source layer disposed on the buffer layer; a gate insulating layer covering the source layer, comprising a first source electrode through-hole and a first drain electrode through-hole; a gate disposed on the gate insulating layer; an interlayer dielectric layer covering the gate, comprising a second source electrode through-hole corresponding to the first source electrode through-hole and a second drain electrode through-hole corresponding to the first drain electrode through-hole; a source drain layer disposed on the interlayer dielectric layer, comprising a source electrode and a drain electrode, the source electrode and the source layer connected by the first source electrode through-hole and the second source electrode through-hole, the drain electrode and the source layer connected by the first drain electrode through-hole and the second drain electrode through-hole.

The gate and the source drain layer are metal electrodes.

The common electrode and the pixel electrode are transparent metallic oxide.

To solve the technical problem above, another proposal offered by the disclosure is: providing a liquid crystal display, the liquid crystal display includes a backlight and a display panel, the display panel includes an array substrate, a color film substrate and a liquid crystal layer between the array substrate and the color film substrate, the array substrate is the one above.

Merits of the disclosure: distinguishing from a conventional technique, a drain electrode of a thin film transistor and a pixel electrode are connected by a conductive layer; on one hand, the conductive layer and a common electrode form an extra capacitor, the extra capacitor and a capacitor formed by the original pixel electrode and the common electrode form a larger capacitor by parallel connection, which can increase capacitance of a pixel storage capacitor and voltage maintenance time of the pixel electrode, preventing appearance of flashing effectively and improving display effects; on the other hand, contact resistance between the conductive layer and the drain electrode of the thin film transistor can be reduced significantly, which can prevent errors in contact of the source electrode and the drain electrode of the thin film transistor caused by over etching when the conductive layer is etched.

### BRIEF DESCRIPTION OF THE DRAWINGS

FIG. 1 is a structural diagram of an array substrate according to a first embodiment of the present disclosure;

FIG. 2 is a structural diagram of an array substrate according to a second embodiment of the present disclosure;

FIG. 3 is a top view of a pixel structure of the array substrate in the second embodiment of the disclosure;

FIG. 4 is a top view of an array substrate in the second embodiment of the disclosure;

FIG. 5 is a structural diagram of a liquid crystal display according to an embodiment of the disclosure.

### DETAILED DESCRIPTION OF PREFERRED EMBODIMENTS

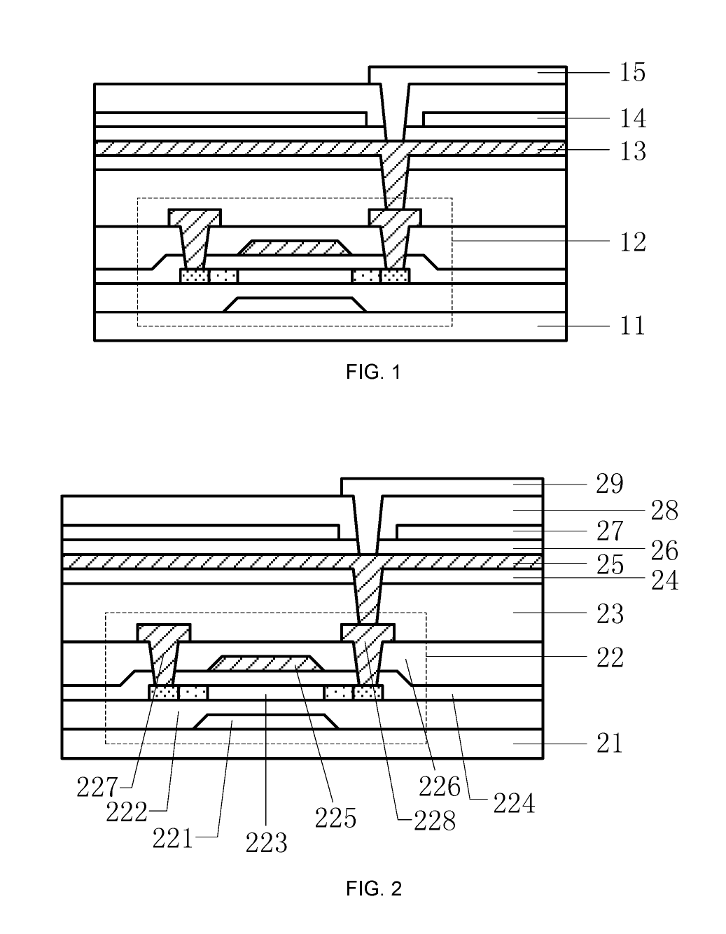

Referring to FIG. 1, a structural diagram of an array substrate according to a first embodiment of the present disclosure, the array substrate includes: a substrate 11; a thin film transistor 12 disposed on the substrate 11; a conductive layer 13 disposed on the thin film transistor 12 and connected with a drain electrode (not labelled) of the thin film transistor 12; a common electrode 14 disposed on the conductive layer 13 and forming a first capacitor Cst1 with the conductor layer 13; a pixel electrode 15 disposed on the common electrode 14 and connected with the conductive layer 13, the pixel electrode 15 and the common electrode 14 form a second capacitor Cst2.

The drain electrode of the thin film transistor 12 and the conductive layer 13 are metal or metallic oxide, the common electrode 14 and the pixel electrode 15 are transparent metallic oxide, such as indium tin oxide ITO.

Optionally, the substrate 11 is a transparent glass substrate, in other embodiments, it can also be a transparent plastic substrate.

Optionally, the thin film transistor 12 can be either a top gate type or a bottom gate type (as shown in FIG. 1), as well as other structures without limitation.

Specifically, the conductive layer 13 and the common electrode 14 have a corresponding section, a shape and an area of the corresponding section can be set according to practical circumstances. Furthermore, the common electrode 14 and the pixel electrode 15 likewise have a corresponding section, a shape and an area of the corresponding section can be set according to practical circumstances as well.

Based on a principle of a parallel plate capacitor C, which is C∝εS/_{d}, where ε is a dielectric constant, S is an area of an overlap section of two parallel plates, d is a distance between two parallel plates, the conductive layer 13 and the common electrode 14 can form a first capacitor Cst1, the common electrode 14 and the pixel electrode 15 can form a second capacitor Cst2. Meanwhile, as the conductive layer 13 and the pixel electrode 15 are connected electrically, therefore, the two capacitors Cst1 and Cst2 can be regarded as two parallel connected capacitors. According to a capacitance parallel connection formula: C=Cst1+Cst2, a sum of capacitance of two parallel capacitors is larger than the capacitance of any one of them, therefore, capacitance of a double-layer capacitor formed by the conductive layer 13, the common electrode 14 and the pixel electrode 15 is larger, which can extend voltage maintenance time of the pixel electrode 15, when the size of a pixel is shrunk, flashing can be prevented effectively, which can improve display effects.

Meanwhile, in a conventional technique, the pixel electrode 15 and the drain electrode of the thin film transistor 12 can be connected electrically, when etching the conductive layer 13, the source electrode and the drain electrode of the thin film transistor 12 can be etched to decrease contact resistance between the pixel electrode 15 and the thin film transistor 12. But in the embodiment, the pixel electrode 15 is connected to the drain electrode of the thin film transistor 12 by the conductive layer 13, on one hand, the contact resistance between conductive layer 13 and the drain electrode of the thin film transistor 12 can be reduced significantly, on the other hand, a contact error can appear in the source electrode and the drain electrode of the thin film transistor 12 caused by over etching.

Furthermore, compared with the pixel electrode 15, the conductive layer 13 has larger electrical conductivity, which can reduce the connection resistance further.

Distinguishing from a conventional technique, a drain electrode of a thin film transistor and a pixel electrode are connected by a conductive layer; on one hand, the conductive layer and a common electrode form an extra capacitor, the extra capacitor and a capacitor formed by the original pixel electrode and the common electrode form a larger capacitor by parallel connection, which can increase capacitance of a pixel storage capacitor and voltage maintenance time of the pixel electrode, preventing appearance of flashing effectively and improving display effects; on the other hand, contact resistance between the conductive layer and the drain electrode of the thin film transistor can be reduced significantly, which can prevent errors in contact of the source electrode and the drain electrode of the thin film transistor caused by over etching when the conductive layer is etched.

Referring to FIG. 2, a structural diagram of an array substrate according to a second embodiment of the present disclosure, the array substrate includes: a substrate 21; a thin film transistor 22 disposed on the substrate 21.

The thin film transistor 22 includes: a light shelter layer 221 disposed on the substrate 21; a buffer layer 222 covering the light shelter layer 221 and the substrate 21; a source layer 223 disposed on the buffer layer 222; a gate insulating layer 224 covering the source layer 223, comprising a first source electrode through-hole (not labelled) and a first drain electrode through-hole (not labelled); a gate 225 disposed on the gate insulating layer 224; an interlayer dielectric layer 226 covering the gate 225, including a second source electrode through-hole (not labelled) corresponding to the first source electrode through-hole and a second drain electrode through-hole (not labelled) corresponding to the first drain electrode through-hole; a source drain layer disposed on the interlayer dielectric layer 226, including a source electrode 227 and a drain electrode 228, the source electrode 227 and the source layer 223 are connected by the first source electrode through-hole and the second source electrode through-hole, the drain electrode 228 and the source layer 223 are connected by the first drain electrode through-hole and the second drain electrode through-hole. The gate 225 and the source drain layer are metal or metallic oxide.

Optionally, the buffer layer 222, the gate insulating layer 224 and the interlayer dielectric layer 226 can be SiOₓ, SiNₓ or a mixture of SiOₓ and SiNₓ.

Optionally, the source layer 223 is amorphous silicon (a-Si) or polysilicon (p-Si), two sides of polysilicon contain a lightly doped region N− and a heavily doped region N+ respectively, the source electrode 227 and the heavily doped region of one side are connected, the drain electrode 228 and the heavily doped region of the other side are connected. Moreover, the source layer 223 can be metallic oxide semiconductor, such as indium gallium zinc oxide (IGZO).

Furthermore, the array substrate further includes: a flat layer 23 covering the thin film transistor 22; a first insulating layer 24 disposed on the flat layer 23; a conductive layer 25 disposed on the first insulating layer 24 and connected with the drain electrode 228 of the thin film transistor 22 by through-holes of the first insulating layer 24 and the flat layer 23; a second insulating layer 26 disposed on the conductive layer 25; a common electrode 27 disposed on the second insulating layer 26 and forming a first capacitor Cst1 with the conductive layer 25; a third insulating layer 28 disposed on the common electrode 27; a pixel electrode 29 disposed on the third insulating layer 28 and connected with the conductive layer 25 by through-holes of the second insulating layer 26 and the third insulating layer 28, the pixel electrode 29 and the common electrode form a second capacitor Cst2.

Optionally, the flat layer 23 can be SiOₓ, SiNₓ or a mixture of SiOₓ and SiNₓ.

Optionally, the first insulating layer 24, the second insulating layer 27 and the third insulating layer 29 can be organic insulating layers manufactured by organic materials, for instance, benzocyclobutene.

Moreover, the array substrate further includes a touch signal line, the touch signal line and the conductive layer 25 are disposed on the same layer within a same process. That is, the touch signal line and the conductive layer 25 are formed in the same coating process, undergoing pattern composition respectively, and they are connected.

Each layer of the array substrate in the embodiments above can be filmed by physical vapor deposition or chemical vapor deposition without limitation.

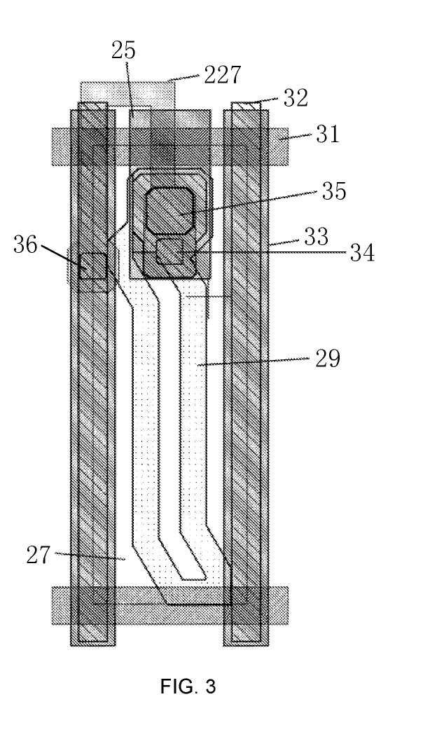

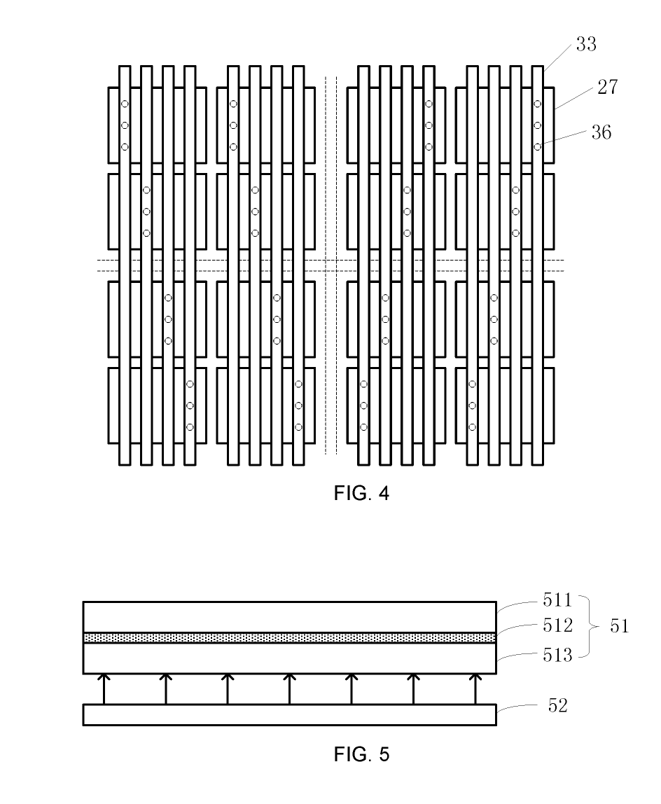

Referring to FIG. 3 and FIG. 4 altogether, FIG. 3 is a top view of a pixel structure of the array substrate in the second embodiment of the disclosure, FIG. 4 is a top view of an array substrate in the second embodiment of the disclosure.

Besides structures same as ones marked in FIG. 2, others included are: a grid line 31, a data line 32, a touch signal line 33, a through-hole 34 of the interlayer dielectric layer 226, a through-hole 35 of the flat layer 23, through-holes 36 of the conductive layer 25 and the common electrode 27.

Specifically, during display, the thin film transistor 22 is turned on, since the data line 32 connected with the source electrode 227, data signals is transmitted to the drain electrode 228 by the thin film transistor 22, reaching the conductive layer 25 and the pixel electrode 29. At this time, the conductive layer 25 and the pixel electrode 29 respectively form capacitors with the common electrode 27, capacitance is enlarged by parallel connecting two capacitors and time for charging pixels is extend.

During touching, the thin film transistor 22 is turned off, touch signals are transmitted to the conductive layer and the pixel electrode 29 by the touch signal line 33. At this time, the conductive layer 25 and the pixel electrode 29 likewise form capacitors respectively with the common electrode 27, capacitance is enlarged by parallel connecting two capacitors and time for charging pixels is extend.

Distinguishing from a conventional technique, according to the disclosure, a drain electrode of a thin film transistor and a pixel electrode are connected by a conductive layer; on one hand, the conductive layer and a common electrode form an extra capacitor, the extra capacitor and a capacitor formed by the original pixel electrode and the common electrode form a larger capacitor by parallel connection, which can increase capacitance of a pixel storage capacitor and voltage maintenance time of the pixel electrode, preventing appearance of flashing effectively and improving display effects; on the other hand, contact resistance between the conductive layer and the drain electrode of the thin film transistor can be reduced significantly, which can prevent errors in contact of the source electrode and the drain electrode of the thin film transistor caused by over etching when the conductive layer is etched.

Referring to FIG. 5, a structural diagram of a liquid crystal display according to an embodiment of the disclosure, the liquid crystal display includes a display panel 51 and a backlight 52, the display panel 51 includes an array substrate 513, a color film substrate 511 and a liquid crystal layer 512 between the array substrate 513 and the color film substrate 511.

The array substrate 513 is the array substrate in the embodiments above with the same structure. More details are glossed over.

Above are embodiments of the present disclosure, which does not limit the scope of the present disclosure. Any modifications, equivalent replacements or improvements within the spirit and principles of the embodiment described above should be covered by the protected scope of the disclosure.

What is claimed is:

1. An array substrate, wherein it comprises:
a substrate;
a thin film transistor disposed on the substrate;
a conductive layer disposed on the thin film transistor and connected with a drain electrode of the thin film transistor;
a common electrode disposed on the conductive layer and forming a first capacitor with the conductor layer;
a pixel electrode disposed on the common electrode and connected with the conductive layer, the pixel electrode and the common electrode forming a second capacitor.

2. The array substrate according to claim 1, wherein an electrical conductivity of the conductive layer is higher than that of the pixel electrode.

3. The array substrate according to claim 2, wherein it further comprises a touch signal line, the touch signal line and the conductive layer are disposed on the same layer within a same process.

4. The array substrate according to claim 1, wherein it further comprises:
a flat layer covering the thin film transistor;
a first insulating layer disposed between the flat layer and the conductive layer;
a second insulating layer disposed between the conductive layer and the common electrode;
a third insulating layer disposed between the common electrode and the pixel electrode.

5. The array substrate according to claim 4, wherein the conductive layer and the drain electrode of the thin film transistor are connected by through-holes of the first insulating layer and the flat layer.

6. The array substrate according to claim 4, wherein the pixel electrode and the conductive layer are connected by through-holes of the second insulating layer and the third insulating layer.

7. The array substrate according to claim 1, wherein the thin film transistor comprises:
a light shelter layer disposed on the substrate;
a buffer layer covering the light shelter layer and the substrate;
a source layer disposed on the buffer layer;
a gate insulating layer covering the source layer, comprising a first source electrode through-hole and a first drain electrode through-hole;
a gate disposed on the gate insulating layer;
an interlayer dielectric layer covering the gate, comprising a second source electrode through-hole corresponding to the first source electrode through-hole and a second drain electrode through-hole corresponding to the first drain electrode through-hole;
a source drain layer disposed on the interlayer dielectric layer, comprising a source electrode and a drain electrode, the source electrode and the source layer connected by the first source electrode through-hole and the second source electrode through-hole, the drain electrode and the source layer connected by the first drain electrode through-hole and the second drain electrode through-hole.

8. The array substrate according to claim 7, wherein the gate and the source drain layer are metal electrodes.

9. The array substrate according to claim 1, wherein the common electrode and the pixel electrode are transparent metallic oxide.

10. A liquid crystal display, comprising a backlight and a display panel, the display panel comprising an array substrate, a color film substrate and a liquid crystal layer between the array substrate and the color film substrate, wherein the array substrate is one of the array substrates in claim 1.
